(19) United States
(12) Patent Application Publication
(10) Pub. No.: US 2026/0286498 A1
(43) Pub. Date: Sep. 24, 2026

(54) DEPOSITION MASK, DEPOSITION APPARATUS INCLUDING DEPOSITION MASK AND ELECTRONIC DEVICE MANUFACTURED USING DEPOSITION MASK

(71) Applicant: Samsung Display Co., LTD., Yongin-si (KR)

(72) Inventor: Sung Woon KIM, Yongin-si (KR)

(21) Appl. No.: 19/391,004

(22) Filed: Nov. 17, 2025

(30) Foreign Application Priority Data
Mar. 18, 2025 (KR) 10-2025-0034667

(51) Int. Cl. C23C 14/04; H10K 71/16

(52) U.S. Cl. CPC C23C 14/042; H10K 71/166

(57) ABSTRACT

A deposition mask includes a mask frame in which a plurality of cell openings is formed, and a membrane located above the mask frame and in which a plurality of pixel openings overlapping the plurality of cell openings is formed, wherein the pixel openings overlapping the cell openings formed in a region different from the central area of the mask frame is located higher than the pixel openings overlapping the cell openings formed in the central area of the mask frame.

This application claims priority to Korean Patent Application No. 10-2025-0034667 filed on Mar. 18, 2025, and all the benefits accruing therefrom under 35 U.S.C. §119, the content of which in its entirety is herein incorporated by reference.

### BACKGROUND

### 1. Field

The present disclosure relates to a deposition mask, a deposition apparatus including the deposition mask, and an electronic device manufactured using the deposition mask.

### 2. Description of the Related Art

A head mounted display (HMD) is an image display device that is worn on a user’s head in the form of glasses or helmets to form a focus at a close distance in front of the user’s eyes. The head mounted display may implement virtual reality (VR) or augmented reality (AR).

The head mounted display magnifies an image displayed on a small display device by using a plurality of lenses, and displays the magnified image. Therefore, a display device applied to the head mounted display may be implemented to provide high-resolution images, for example, images with a resolution of 3000 PPI (Pixels Per Inch) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is located on a semiconductor wafer substrate including complementary metal oxide semiconductor (CMOS).

In order to manufacture a display panel with a high resolution of 3000 PPI or higher, a high-resolution deposition mask may be utilized. For example, the deposition mask may be manufactured by forming a membrane having a plurality of pixel openings on a substrate such as a silicon wafer, and partially etching the substrate to form cell openings that expose the pixel openings.

A deposition mask may be used in a deposition process for forming organic light emitting layers on a backplane substrate. While the deposition process is being performed, the backplane substrate may be located on the deposition mask, and a deposition source for providing a vapor deposition material may be located under the deposition mask. The vapor deposition material may be deposited on the backplane substrate through pixel openings of the deposition mask.

### SUMMARY

Aspects of the present disclosure provide a deposition mask capable of improving a deposition accuracy of an organic light emitting layer deposited on a backplane substrate, a deposition apparatus including the deposition mask, and an electronic device manufactured using the deposition mask.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a deposition mask includes a mask frame in which a plurality of cell openings are formed, and a membrane located above the mask frame and in which a plurality of pixel openings overlapping the plurality of cell openings are formed, wherein, among the plurality of pixel openings and the plurality of cell openings, pixel openings overlapping cell openings formed in a region different from a central area of the mask frame are located higher than pixel openings overlapping cell openings formed in the central area of the mask frame.

The membrane is divided into a plurality of mask cell regions located on top portions of the plurality of cell openings, and a grid region located on a top portion of the mask frame excluding the plurality of cell openings, and the plurality of pixel openings are formed in the plurality of mask cell regions.

Among the plurality of pixel openings and the plurality of mask cell regions, the pixel openings formed in a mask cell region located in a central area of the mask frame are located on a same imaginary horizontal surface as a portion of the membrane located in the grid region.

Among the plurality of pixel openings and the plurality of mask cell regions, pixel openings formed in the mask cell regions located in a region different from the central area of the mask frame are located higher than a portion of the membrane located in the grid region.

The plurality of cell openings include a first cell opening formed in a central area of the mask frame, a second cell opening formed in an edge portion of the mask frame, and a third cell opening formed between the first cell opening and the second cell opening, wherein among the plurality of pixel openings, pixel openings overlapping the second cell opening are located higher than pixel openings overlapping the first cell opening and the third cell opening.

Among the plurality of pixel openings, the pixel openings overlapping the third cell opening are located higher than top portions of the pixel openings overlapping the first cell opening and lower than bottom portions of the pixel openings overlapping the second cell opening.

A portion of the membrane overlaps a cell opening formed in the region different from a central area of the mask frame and includes a plurality of upper flat portions located higher than a top portion of the membrane located in the grid region, and the plurality of pixel openings are formed in the plurality of upper flat portions.

The portion of the membrane which overlaps the cell opening formed in the region different from the central area of the mask frame further includes a plurality of lower flat portions located on a same imaginary horizontal surface as the top portion of the membrane located in the grid region, and a plurality of connection portions connecting the plurality of upper flat portions and the plurality of lower flat portions.

The membrane includes an inorganic layer located on a top portion of the mask frame, and a nitride layer located on a top portion of the inorganic layer, wherein the plurality of pixel openings are formed in the nitride layer.

In the inorganic layer, the plurality of cell openings and a plurality of inorganic layer openings are formed.

The deposition mask further includes a rear inorganic layer located on a bottom portion of the mask frame, wherein, in the rear inorganic layer, a plurality of rear openings overlapping the plurality of cell openings are formed.

According to an aspect of the present disclosure, a deposition device includes a deposition mask, and a deposition source located below the deposition mask and emitting a deposition material toward the deposition mask, wherein the deposition mask includes a mask frame in which a plurality of cell openings are formed, and a membrane located on a top portion of the mask frame and in which a plurality of pixel openings overlapping the plurality of cell openings are formed, and among the plurality of pixel openings, pixel openings formed in a region different from a region overlapping the deposition source are located higher than pixel openings formed in the region overlapping the deposition source.

The membrane is divided into a plurality of mask cell regions located on top portions of the plurality of cell openings, and a grid region located on a top portion of the mask frame excluding the plurality of cell openings, and the plurality of pixel openings are formed in the plurality of mask cell regions

Among the plurality of pixel openings and the plurality of mask cell regions, pixel openings formed in a mask cell region located in the region overlapping the deposition source are located on a same imaginary horizontal surface as a portion of the membrane located in the grid region.

Among the plurality of pixel openings and the plurality of mask cell regions, pixel openings formed in mask cell regions located in the region different from the region overlapping the deposition source are located higher than a portion of the membrane located in the grid region.

The plurality of cell openings includes a first cell opening formed in the region overlapping the deposition source, a second cell opening formed in an edge region of the mask frame, and a third cell opening formed between the first cell opening and the second cell opening, wherein among the plurality of pixel openings, pixel openings overlapping the second cell opening are located higher than pixel openings overlapping the first cell opening and the third cell opening.

Among the plurality of pixel openings, the pixel openings overlapping the third cell opening are located higher than the pixel openings overlapping the first cell opening, and lower than the pixel openings overlapping the second cell opening.

A portion of the membrane which overlaps a cell opening formed in the region different from the region overlapping the deposition source includes a plurality of upper flat portions located higher than the membrane located in the grid region, and the plurality of pixel openings are formed in the plurality of upper flat portions.

The portion of the membrane which overlaps the cell opening formed in the region different from the region overlapping the deposition source further includes a plurality of lower flat portions located on a same imaginary horizontal surface as a portion of the membrane located in the grid region, and a plurality of connection portions connecting the plurality of upper flat portions and the plurality of lower flat portions.

According to an aspect of the present disclosure, an electronic device includes a display device manufactured using a deposition mask, wherein the deposition mask includes a mask frame in which a plurality of cell openings are formed, and a membrane located above the mask frame and in which a plurality of pixel openings overlapping the plurality of cell openings are formed, wherein, among the plurality of pixel openings and the plurality of mask cell regions, pixel openings overlapping cell openings formed in a region different from the central area of the mask frame are located higher than the pixel openings overlapping cell openings formed in the central area of the mask frame.

In accordance with the deposition mask, the deposition apparatus including the deposition mask, and the electronic device manufactured using the deposition mask according to the present disclosure, pixel openings overlapping cell openings formed in an area different from the central area of a mask frame are positioned higher than pixel openings overlapping cell openings formed in the central area of the mask frame, thereby improving deposition accuracy of an organic light emitting layer deposited on a backplane substrate.

The effects according to the embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic exploded perspective view illustrating a display device according to an embodiment;

FIG. 2 is a schematic plan view illustrating the display device illustrated in FIG. 1;

FIG. 3 is an equivalent circuit diagram illustrating an example of a first sub-pixel illustrated in FIG. 2;

FIG. 4 is a schematic plan view illustrating an example of the display panel illustrated in FIG. 1;

FIG. 5 is a schematic enlarged plan view illustrating an example of the display area of FIG. 4;

FIG. 6 is a schematic enlarged plan view illustrating another example of the display area of FIG. 4;

FIG. 7 is a schematic cross-sectional view illustrating an example of a display panel taken along line I1-I1’ of FIG. 5;

FIG. 8 is a schematic cross-sectional view illustrating another example of a display panel taken along line I1-I1’ of FIG. 5;

FIG. 9 is a perspective view illustrating an example of a head mounted display;

FIG. 10 is an exploded perspective view illustrating the head mounted display of FIG. 9;

FIG. 11 is a perspective view illustrating another example of a head mounted display;

FIG. 12 is a schematic diagram illustrating a deposition apparatus according to an embodiment;

FIG. 13 is a schematic bottom view illustrating the backplane substrate illustrated in FIG. 12;

FIG. 14 is a schematic plan view illustrating a deposition mask according to an embodiment of the present disclosure;

FIG. 15 is an enlarged view of part A of FIG. 14;

FIG. 16 is a cross-sectional view taken along line I2-I2’ of FIG. 15;

FIG. 17 is a cross-sectional view taken along line I3-I3’ of FIG. 15;

FIG. 18 is a cross-sectional view taken along line I4-I4’ of FIG. 15;

FIG. 19 is a view illustrating a step of preparing a nitride layer in a method of manufacturing a deposition mask according to an embodiment according to the present disclosure;

FIG. 20 is a view illustrating a state in which a part of the nitride layer is removed in FIG. 19;

FIG. 21 is a view illustrating a state in which an inorganic layer, a mask frame, and a rear inorganic layer are formed in FIG. 20;

FIG. 22 is a view illustrating a state in which a pixel opening is formed in FIG. 21;

FIG. 23 is a view illustrating a state in which an inorganic layer opening, a cell opening, and a rear opening are formed in FIG. 22;

FIG. 24 is a view illustrating a state in which a part of the nitride layer is removed in FIG. 23;

FIG. 25 is a block diagram of an electronic device according to an embodiment; and

FIG. 26 is schematic views of electronic devices according to various embodiments.

### DETAILED DESCRIPTION

Advantages and features of the present disclosure and methods to achieve them will become apparent from the descriptions of example embodiments hereinbelow with reference to the accompanying drawings. However, the present disclosure is not limited to example embodiments disclosed herein but may be implemented in various different ways. The example embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are illustrative and are not limiting.

Although terms such as first, second, and the like are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Features of various example embodiments of the present disclosure may be combined partially or totally. As will be clearly appreciated by those skilled in the art, technically various interactions and operations are possible. Various example embodiments can be practiced individually or in combination.

Hereinafter, example embodiments of the present disclosure will be described in detail with reference to the accompanying drawings.

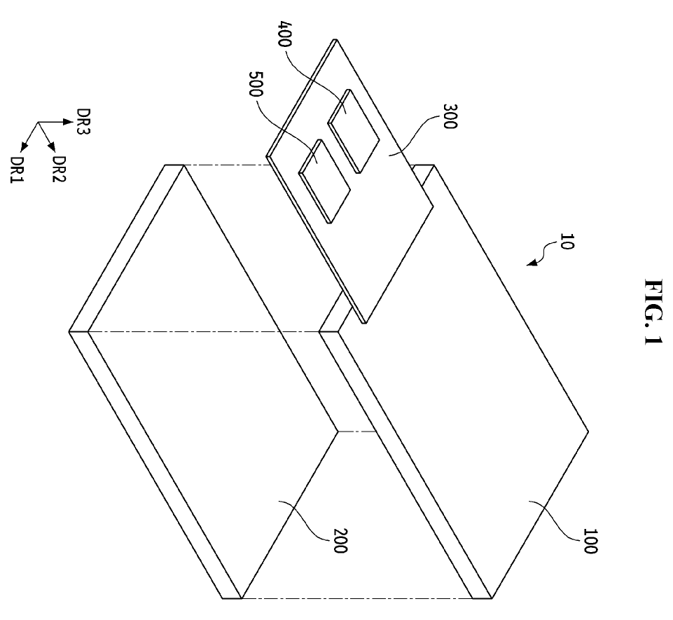

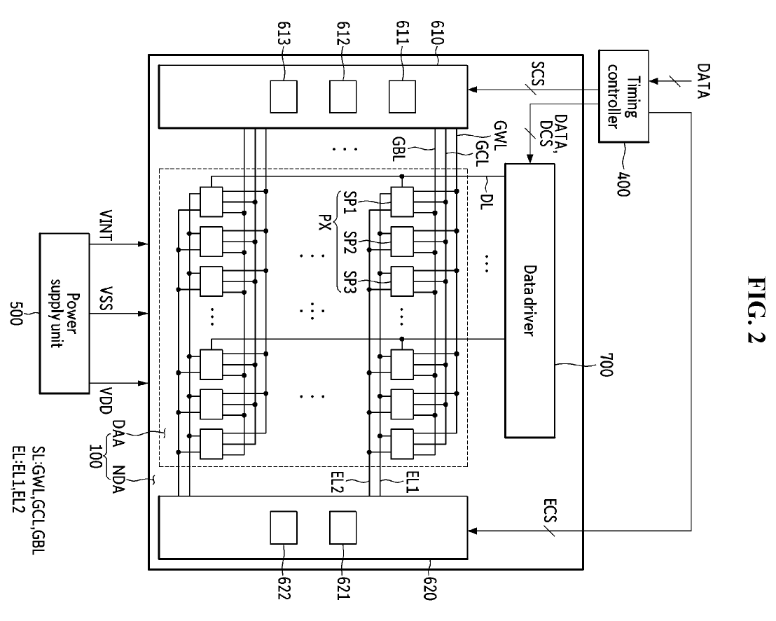

FIG. 1 is a schematic exploded perspective view illustrating a display device according to an embodiment. FIG. 2 is a schematic plan view illustrating the display device illustrated in FIG. 1.

Referring to FIGS. 1 and 2, a display device 10 according to an embodiment is a device displaying a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to an embodiment may be applied as a display unit of a television, a laptop, a monitor, a billboard, or an Internet-of-Things (IoT) terminal. Alternatively, the display device 10 according to an embodiment may be applied to a smart watch, a watch phone, a head mounted display (HMD) for implementing virtual reality and augmented reality, and the like.

The display device 10 according to an embodiment includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a selected curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but embodiments of the present disclosure are not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as illustrated in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

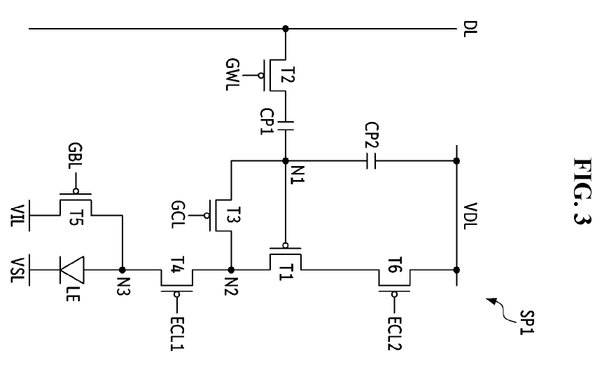

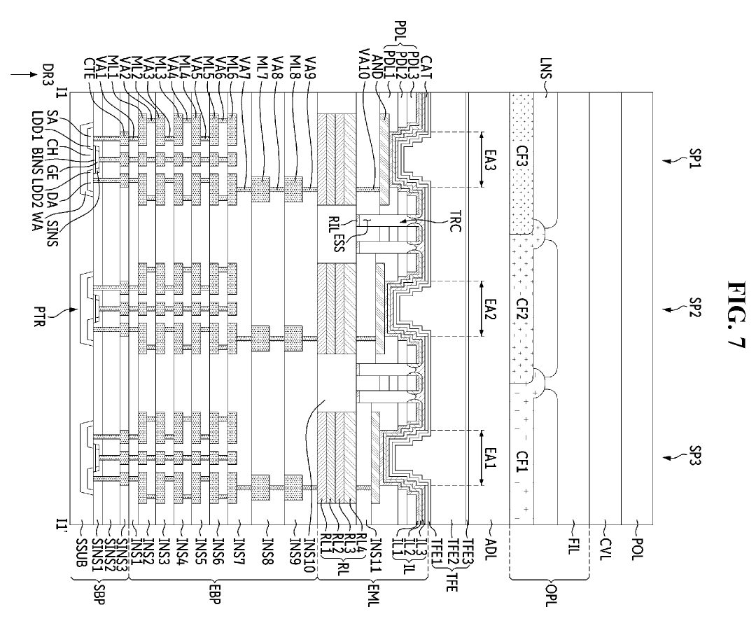

The plurality of pixels PX include a plurality of sub-pixels SP1, SP2, and SP3. The plurality of sub-pixels SP1, SP2, and SP3 may include a plurality of pixel transistors as illustrated in FIG. 3, and the plurality of pixel transistors may be formed by a semiconductor process and located on a semiconductor substrate SSUB (see FIG. 7). For example, the plurality of pixel transistors of the data driver 700 may be formed as complementary metal oxide semiconductor (CMOS) transistors, but embodiments of the present disclosure are not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be located in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed as CMOS transistors, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed on the semiconductor substrate SSUB (see FIG. 7) through a semiconductor process. For example, the plurality of data transistors may be formed as CMOS transistors, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface, e.g., the rear surface, of the display panel 100. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

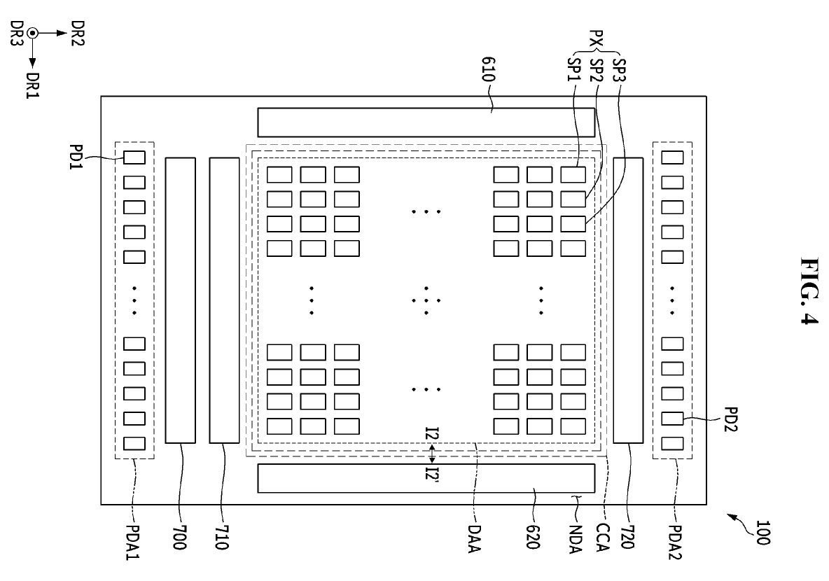

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed as CMOS transistors, but embodiments of the present disclosure are not limited thereto. Each of the timing control circuit 400 and the power supply circuit 500 may be located between the data driver 700 and the first pad portion PDA1 (see FIG. 4).

FIG. 3 is an equivalent circuit diagram illustrating an example of a first sub-pixel illustrated in FIG. 2.

Referring to FIG. 3, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 includes a plurality of transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE may be proportional to the driving current Ids. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer located between the first electrode and the second electrode, but embodiments of the present disclosure are not limited thereto. For example, the light emitting element LE may be an inorganic light emitting element including a first electrode, a second electrode, and an inorganic semiconductor located between the first electrode and the second electrode, in which case the light emitting element LE may be a micro light emitting diode.

The first transistor T1 may be a driving transistor that controls a source-drain current Ids (hereinafter referred to as “driving current”) flowing between the source electrode and the drain electrode according to a voltage applied to the gate electrode.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be located between a first node N1 and a second node N2. The third transistor T3 is turned on by the write control signal of the write control line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be located between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a p-type MOSFET, but embodiments of the present disclosure are not limited thereto. Each of the first to sixth transistors T1 to T6 may be an n-type MOSFET. Alternatively, some of the first to sixth transistors T1 to T6 may be p-type MOSFETs, and each of the remaining transistors may be an n-type MOSFET.

Although it is illustrated in FIG. 3 that the first sub-pixel SP1 includes six transistors T1 to T6 and two capacitors CP1 and CP2, it should be noted that the equivalent circuit diagram of the first sub-pixel SP1 is not limited to that illustrated in FIG. 3. For example, the number of transistors and the number of capacitors of the first sub-pixel SP1 are not limited to those illustrated in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a schematic plan view illustrating an example of the display panel illustrated in FIG. 1.

Referring to FIG. 4, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. However, embodiments of the present disclosure are not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2.

A cathode connection portion CCA may be a region in which a second electrode CAT (see FIG. 7) of a display element layer EML (see FIG. 7) is connected to the first driving voltage line VSL of the non-display area NDA. The cathode connection portion CCA may be located outside at least one side of the display area DAA. For example, the cathode connection portion CCA may be located outside at least on one side among the left side, the right side, the upper side, and the lower side of the display area DAA. Alternatively, the cathode connection portion CCA may be located to surround the display area DAA as illustrated in FIG. 4 in order to minimize a deviation in the first driving voltage VSS due to a voltage drop (IR drop) or voltage rise (IR rising) of the second electrode CAT in the display area DAA.

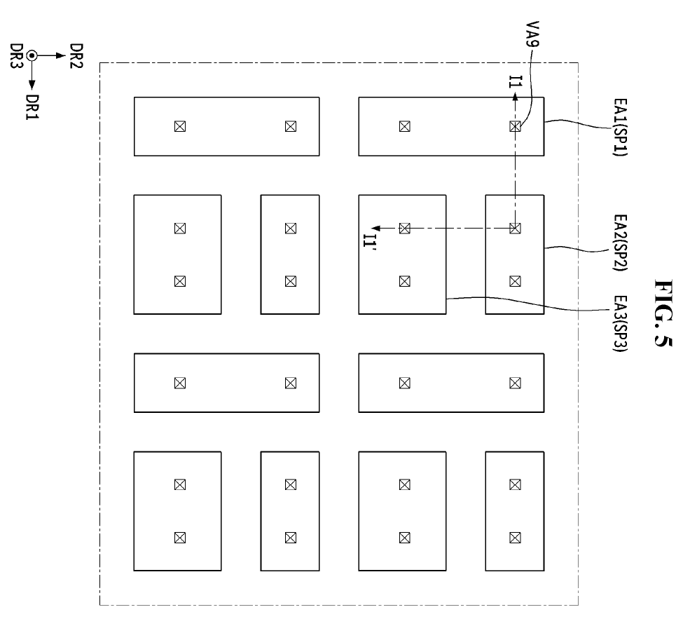

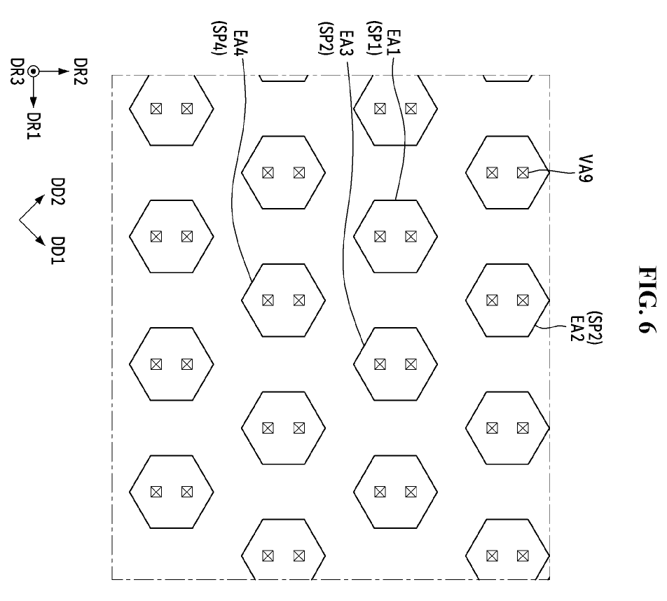

FIG. 5 is a schematic enlarged plan view illustrating an example of the display area of FIG. 4. FIG. 6 is a schematic enlarged plan view illustrating another example of the display area of FIG. 4.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in plan view, a quadrilateral or hexagonal shape as illustrated in FIGS. 5 and 6, but embodiments of the present disclosure are not limited thereto. The first emission area EA1, the second emission area EA2, and the third emission area EA3 may have a polygonal shape other than a quadrangle or hexagon, a circular shape, an elliptical shape, or an atypical shape in plan view.

As illustrated in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In some aspects, the second emission area EA2 and the third emission area EA3 may be adjacent to each other in the second direction DR2. The area of the first emission area EA1, the area of the second emission area EA2, and the area of the third emission area EA3 may be different.

Alternatively, as illustrated in FIG. 6, the emission areas EA1, EA2, EA3, and EA4 may have a hexagonal shape in plan view. In this case, the first emission area EA1 and the third emission area EA3 may be adjacent in the first direction DR1, and the second emission area EA2 and the fourth emission area EA4 may be adjacent in the second direction DR2. In some aspects, the first emission area EA1 and the second emission area EA2 may be adjacent in a first diagonal direction DD1, and the second emission area EA2 and the third emission area EA3 may be adjacent in a second diagonal direction DD2. In some aspects, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

Each of the plurality of pixels PX may include three emission areas EA1, EA2, and EA3 as illustrated in FIG. 5, or may include four emission areas EA1, EA2, EA3, and EA4 as illustrated in FIG. 6. In this case, the fourth emission area EA4 may emit the same second light as the second emission area EA2, but embodiments of the present disclosure are not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombus shape, or a hexagonal structure in which the emission areas each having a hexagonal shape are arranged as illustrated in FIG. 6.

FIG. 7 is a schematic cross-sectional view illustrating an example of a display panel taken along line I1-I1’ of FIG. 5.

Referring to FIG. 7, the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB. The plurality of well regions WA may be regions doped with a second type impurity. The second type impurity may be different from the aforementioned first type impurity. In an example in which the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, which may result in an increase of the length of the channel region CH of each of the pixel transistors PTR.

A first semiconductor insulating film SINS1 may be located on the semiconductor substrate SSUB. A second semiconductor insulating film SINS2 may be located on the first semiconductor insulating film SINS1.

The plurality of contact terminals CTE may be located on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film SINS2. The plurality of contact terminals CTE may include any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be located on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be formed as a silicon carbonitride (SiCN) or silicon oxide (SiOₓ)-based inorganic film, but embodiments of the present disclosure are not limited thereto.

The semiconductor substrate SSUB may be replaced with a glass substrate or a polymer resin substrate such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of insulating films INS1 to INS9. In some aspects, the light emitting element backplane EBP includes a plurality of insulating films INS1 to INS9 located between first to eighth conductive layers ML1 to ML8.

First to eighth insulating films INS1 to INS8 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 illustrated in FIG. 3.

For example, the first to sixth transistors T1 to T6 are formed in the semiconductor backplane SBP, and the connection of the first to sixth transistors T1 to T6 and the first and second capacitors CP1 and CP2 is accomplished through the first to eighth conductive layers ML1 to ML8. In some aspects, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may include substantially the same material. The first to eighth conductive layers ML1 to ML8 and the first to eighth vias VA1 to VA8 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may include substantially the same material. The first to eighth insulating films INS1 to INS8 may be formed as silicon oxide (SiOₓ)-based inorganic films, but embodiments of the present disclosure are not limited thereto.

A ninth insulating film INS9 may be located on the eighth insulating film INS8 and the eighth conductive layer ML8. The ninth insulating film INS9 may be formed as a silicon oxide (SiOₓ)-based inorganic film, but embodiments of the present disclosure are not limited thereto.

Each of the ninth vias VA9 may penetrate the ninth insulating film INS9 and be connected to the exposed eighth conductive layer ML8. The ninth vias VA9 may include any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be located on the light emitting element backplane EBP. The display element layer EML may include tenth and eleventh insulating films INS10 and INS11, a reflective electrode RL, the first electrodes AND, a light emitting stack IL, the second electrode CAT, a pixel defining film PDL, and a plurality of trenches TRC.

The reflective electrode RL may be located on the ninth insulating film INS9. The reflective electrode RL may include at least one reflective electrode RL1, RL2, RL3, and RL4. For example, the reflective electrode RL may include first to fourth reflective electrodes RL1, RL2, RL3, and RL4 as illustrated in FIG. 7.

The first reflective electrodes RL1 may be located on the ninth interlayer insulating film INS9, and may be connected to the ninth via VA9. Each of the second reflective electrodes RL2 may be located on the first reflective electrode RL1 corresponding thereto. Each of the third reflective electrodes RL3 may be located on the second reflective electrode RL2 corresponding thereto. Each of the fourth reflective electrodes RL4 may be located on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth interlayer insulating film INS10 may be located on the ninth interlayer insulating film INS9. The tenth interlayer insulating film INS10 may be located between the reflective electrodes RL adjacent to each other. The tenth interlayer insulating film INS10 may be a film for flattening a stepped portion caused by the reflective electrodes RL. The eleventh interlayer insulating film INS11 may be located on the tenth interlayer insulating film INS10 and a reflective electrode layer RL.

The tenth interlayer insulating film INS10 and the eleventh interlayer insulating film INS11 may be formed as silicon oxide (SiOₓ)-based inorganic films, but embodiments of the present disclosure are not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode layer RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as illustrated in FIG. 7, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode layer RL in the first sub-pixel SP1 is greater than the distance between the first electrode AND and the reflective electrode layer RL in the second sub-pixel SP2. In some aspects, the distance between the first electrode AND and the reflective electrode layer RL in the second sub-pixel SP2 is greater than the distance between the first electrode AND and the reflective electrode layer RL in the third sub-pixel SP3.

Each of the tenth vias VA10 may penetrate the eleventh interlayer insulating film INS11 and be connected to the exposed fourth reflective electrodes RL4. The tenth vias VA10 may include any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be located on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be located on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is located.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be located on the edge of the first electrode AND of each of the light emitting elements LE, the second pixel defining film PDL2 may be located on the first pixel defining film PDL1, and the third pixel defining film PDL3 may be located on the second pixel defining film PDL2. The first pixel defining film PDL1, the second pixel defining film PDL2, and the third pixel defining film PDL3 may be formed as silicon oxide (SiOₓ)-based inorganic films. Alternatively, the first pixel defining film PDL1 and the third pixel defining film PDL3 may be formed as silicon nitride (SiNₓ)-based inorganic films, whereas the second pixel defining film PDL2 may be formed as a silicon oxide (SiOₓ)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be located between the neighboring sub-pixels SP1, SP2, and SP3. Although FIG. 7 illustrates that two trenches TRC are located between the neighboring sub-pixels SP1, SP2, and SP3, embodiments of the present disclosure are not limited thereto.

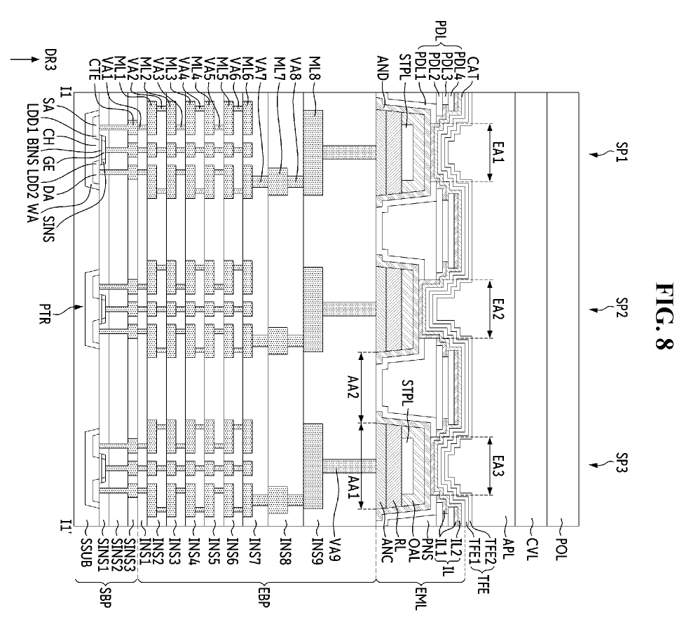

The light emitting stack IL may include a plurality of stack layers IL1, IL2, and IL3. FIG. 7 illustrates that the light emitting stack IL has a three-tandem structure including a first stack layer IL1, a second stack layer IL2, and a third stack layer IL3, but embodiments of the present disclosure are not limited thereto. For example, the light emitting stack IL may have a two-tandem structure including two stack layers as illustrated in FIG. 8.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be located between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be located on the first electrodes AND and the pixel defining film PDL, and a residual film RIL located on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be located on the first stack layer IL1. Due to the trench TRC, the second stack layer IL2 may be cut off between the neighboring sub-pixels SP1, SP2, and SP3. A cavity ESS or an empty space may be located between the residual film RIL and the second stack layer IL2 in the trench TRC. The third stack layer IL3 may be located on the second stack layer IL2. The third stack layer IL3 is not cut off by the trench TRC and may be located such that the third stack layer IL3 covers the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In some aspects, in the two-tandem structure, each of the plurality of trenches TRC may be a structure for cutting off the charge generation layer and the lower stack layer located between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, another structure may exist instead of the trench TRC. For example, instead of the trench TRC, a reverse tapered partition wall may be located on the pixel defining film PDL.

In some aspects, FIG. 7 illustrates that the light emitting stack IL that emits light is located in the first emission area EA1, the second emission area EA2, and the third emission area EA3, but embodiments of the present disclosure are not limited thereto. For example, instead of the light emitting stack IL, the first light emitting layer may be located in the first emission area EA1, and may be omitted from the second emission area EA2 and the third emission area EA3. Furthermore, the second light emitting layer may be located in the second emission area EA2 and may be omitted from the first emission area EA1 and the third emission area EA3. Furthermore, the third light emitting layer may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the light emitting stack IL. The second electrode CAT may be located on the third stack layer IL3 in each of the plurality of trenches TRC. The second electrode CAT may include a transparent conductive material (TCO) such as ITO or IZO that can transmit light or a semi-transmissive conductive material such as magnesium (Mg), silver (Ag), or an alloy of Mg and Ag. In an example in which the second electrode CAT includes a semi-transmissive conductive material, the light emission efficiency may be improved in each of the first to third sub-pixels SP1, SP2, and SP3 due to a micro-cavity effect.

The encapsulation layer TFE may be located on the display element layer EML. The encapsulation layer TFE may include at least one inorganic film TFE1 and TFE3 to prevent oxygen or moisture from permeating into the display element layer EML. For example, the first encapsulation inorganic film TFE1 may be located on the second electrode CAT, and the second encapsulation inorganic film TFE3 may be located above the first encapsulation inorganic film TFE1. The first encapsulation inorganic film TFE1 and the second encapsulation inorganic film TFE3 may be formed as multiple films in which one or more inorganic films of silicon nitride (SiNₓ), silicon oxynitride (SiON), silicon oxide (SiOₓ), titanium oxide (TiOₓ), and aluminum oxide (AlOₓ) layers are alternately stacked.

In some aspects, the encapsulation layer TFE may include at least one organic film TFE2 to protect the display element layer EML from foreign substances such as dust. For example, the encapsulation organic film TFE2 may be located between the first encapsulation inorganic film TFE1 and the second encapsulation inorganic film TFE3. The encapsulation organic film TFE2 may be a monomer. Alternatively, the encapsulation organic film TFE2 may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In some aspects, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be located on the plurality of lenses LNS. The filling layer FIL may have a selected refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be located on the filling layer FIL. The cover layer CVL may be a glass substrate or a polymer resin. In an example in which the cover layer CVL is a glass substrate, the cover layer CVL may be attached onto the filling layer FIL. In this case, the filling layer FIL may serve to bond the cover layer CVL. In an example in which the cover layer CVL is a glass substrate, the cover layer CVL may serve as an encapsulation substrate. In an example in which the cover layer CVL is a polymer resin, the cover layer CVL may be directly applied onto the filling layer FIL.

The polarizing plate may be located on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but embodiments of the present disclosure are not limited thereto. However, when visibility degradation caused by reflection of external light is sufficiently overcome by the first to third color filters CF1, CF2, and CF3, the polarizing plate may be omitted.

FIG. 8 is a schematic cross-sectional view illustrating another example of a display panel taken along line I1-I1’ of FIG. 5.

The embodiment of FIG. 8 differs from the embodiment of FIG. 7 in that the first electrode and of each of the light emitting elements LE is in contact with and electrically connected to the side surface of a connection electrode ANC connected to the eighth conductive layer ML8. The embodiment of FIG. 8 also differs from the embodiment of FIG. 7 in that the trench TRC is omitted, and instead, the third pixel defining film PDL3 and a fourth pixel defining film PDL4 have an eaves-shaped or mushroom-shaped cross-sectional structure. In the embodiment of FIG. 8, redundant description of parts already described in the embodiment of FIG. 7 will be omitted.

Referring to FIG. 8, the plurality of connection electrodes ANC may be respectively located on first portions AA1 of the ninth insulating film INS9. Each of the plurality of connection electrodes ANC may be located on the first portion AA1 of the ninth insulating film INS9 corresponding thereto. A plurality of connection electrodes ANC may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively located on the plurality of connection electrodes ANC. Each of the plurality of reflective electrodes RL may be located on the connection electrode ANC corresponding thereto. The plurality of reflective electrodes RL may include any one of copper (Cu), aluminum (Al), tungsten (W), molybdenum (Mo), chromium (Cr), gold (Au), titanium (Ti), nickel (Ni), and neodymium (Nd), or an alloy including any one of them. For example, each of the plurality of reflective electrodes RL may include aluminum (Al) having high reflectivity.

A plurality of optical auxiliary films OAL may be respectively located on the plurality of reflective electrodes RL. Each of the plurality of optical auxiliary films OAL may be located on the reflective electrode RL corresponding thereto. The plurality of optical auxiliary films OAL may be formed as silicon oxide (SiOₓ)-based inorganic films, but embodiments of the present disclosure are not limited thereto.

In each of the first emission area EA1 and the third emission area EA3, a step layer STPL may be located on the reflective electrode RL, and the optical auxiliary film OAL may be located on the step layer STPL. In the second emission area EA2, the optical auxiliary film OAL may be located on the reflective electrode RL, and the step layer STPL may be omitted. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light emitting stack IL, and the wavelength and resonance distance of light emitted from the second stack layer IL2.

Each of the light emitting elements LE may include the first electrode and, the light emitting stack IL, and the second electrode CAT.

The first electrode AND of each of the light emitting elements LE may be located on the optical auxiliary film OAL corresponding thereto. Since the connection electrode ANC, the reflective electrode RL, and the optical auxiliary film OAL are sequentially stacked, the first electrode and of each of the light emitting elements LE may be located on the top surface and the side surface of the optical auxiliary film OAL, the side surface of the reflective electrode RL, and the side surface of the connection electrode ANC. Accordingly, the first electrode and of each of the light emitting elements LE may be in contact with and electrically connected to the side surface of the reflective electrode RL and the side surface of the connection electrode ANC. Therefore, compared to when the first electrode and of each of the light emitting elements LE is connected to the reflective electrode RL exposed through a through hole penetrating the optical auxiliary film OAL, the number of mask processes may be reduced, thereby advantageously lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth insulating film INS9 may be substantially the same.

Alternatively, the thickness of the first portion AA1 of the ninth insulating film INS9 may be greater than the thickness of the second portion AA2. In this case, the side surface of the first portion AA1 of the ninth insulating film INS9 may be exposed, and the first electrode AND of each of the light emitting elements LE may be located on the exposed side surface of the first portion AA1 of the ninth insulating film INS9.

The first electrode AND of each of the light emitting elements LE may include any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the first electrode AND of each of the light emitting elements LE may include titanium (Ti), titanium nitride (TiN), indium tin oxide (ITO), or indium zinc oxide (IZO), but embodiments of the present disclosure are not limited thereto.

The pixel defining film PDL may be located on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be located on the first electrode and of each of the light emitting elements LE. Specifically, the first pixel defining film PDL1 may cover a part of the top surface of the first electrode and located on the optical auxiliary film OAL. Further, the first pixel defining film PDL1 may cover the first electrode and located on the side surface of the connection electrode ANC, the side surface of the reflective electrode RL, and the side surface of the optical auxiliary film OAL. The first pixel defining film PDL1 may be located on the top surface of the second portion AA2 of the ninth insulating film INS9.

A planarization film PNS is a film for flattening the stepped portion caused by the connection electrode ANC, the reflective electrode RL, and the optical auxiliary film OAL.

The planarization film PNS may be located on the first pixel defining film PDL1 covering the first electrode and located on the side surface of the connection electrode ANC, the side surface of the reflective electrode RL, and the side surface of the optical auxiliary film OAL. The planarization film PNS may be located on the first pixel defining film PDL1 located on the second portion AA2 of the ninth insulating film INS9.

The planarization film PNS may be located between the connection electrodes ANC adjacent in the first direction DR1 or the second direction DR2. The planarization film PNS may be located between the reflective electrodes RL adjacent in the first direction DR1 or the second direction DR2. The planarization film PNS may be located between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 located on the top surface of the first electrode AND located in the second emission area EA2.

In contrast, the top surface of the planarization film PNS may be flatly connected to the top surface of the first pixel defining film PDL1 located on the top surface of the first electrode and located in the first emission area EA1 and the third emission area EA3. That is, the planarization film PNS may not cover the top surface of the first pixel defining film PDL1 located on the top surface of the first electrode and located in each of the first emission area EA1 and the third emission area EA3.

The second pixel defining film PDL2 may be located on the first pixel defining film PDL1 and the planarization film PNS, the third pixel defining film PDL3 may be located on the second pixel defining film PDL2, and the fourth pixel defining film PDL4 may be located on the third pixel defining film PDL3. The first pixel defining film PDL1 and the third pixel defining film PDL3 may be formed as silicon nitride (SiNₓ)-based inorganic films, whereas the second pixel defining film PDL2, the fourth pixel defining film PDL4, and the planarization film PNS may be formed as silicon oxide (SiOₓ)-based inorganic films. The first pixel defining film PDL1 includes a material different from a material of the planarization film PNS, and thus may serve as a stopper in a chemical mechanical polishing process for the planarization film PNS.

When the planarization film PNS and the second pixel defining film PDL2 are both formed as a silicon oxide (SiOₓ)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. In some embodiments, the third pixel defining film PDL3 and the fourth pixel defining film PDL4 may have an eave-shaped or mushroom-shaped cross-sectional structure.

The light emitting stack IL may be located on the first electrode and and the pixel defining film PDL. The light emitting stack IL may include the first stack layer IL1 and the second stack layer IL2 that emit different lights. In an example in which the light emitting stack IL has a two-tandem structure, one of the first stack layer IL1 and the second stack layer IL2 may emit light that includes the wavelength range of any one of the first light, the second light, and the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be located between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metal material.

The first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In this case, the first hole transport layer of the first stack layer IL1, and a charge generation layer CGL located between the first stack layer IL1 and the second stack layer IL2 may also be cut off. Further, although FIG. 8 illustrates that the second stack layer IL2 is connected without being cut off, the second hole transport layer of the second stack layer IL2 may be cut off, and the second electron transport layer of the second stack layer IL2 may be connected without being cut off. Therefore, embodiments of the present disclosure may prevent a leakage current from flowing through the first hole transport layer of the first stack layer IL1, the second hole transport layer of the second stack layer IL2, and the charge generation layer CGL between the adjacent emission areas EA1, EA2, and EA3. Accordingly, embodiments of the present disclosure may prevent the light emitting stack IL in the adjacent emission areas EA1, EA2, and EA3 from emitting light other than the originally intended light due to the influence of the above current.

Although FIG. 8 illustrates a two-tandem structure in which the light emitting stack IL includes two stack layers IL1 and IL2, embodiments of the present disclosure are not limited thereto. For example, the light emitting stack IL may have a three-tandem structure including three stack layers as illustrated in FIG. 7. In this case, the light emitting stack IL may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. Alternatively, as illustrated in FIG. 7, the trench TRC penetrating the first pixel defining film PDL1, the planarization film PNS, the second pixel defining film PDL2, and the third pixel defining film PDL3 may be added. In this case, the trench TRC may penetrate at least a part of the ninth insulating film INS9, but embodiments of the present disclosure are not limited thereto.

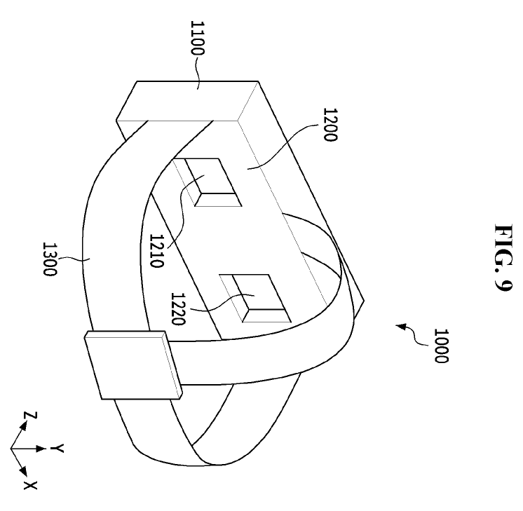

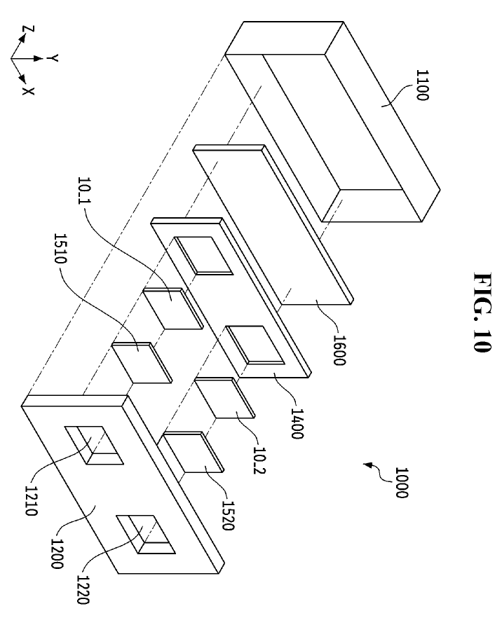

FIG. 9 is a perspective view illustrating an example of a head mounted display. FIG. 10 is an exploded perspective view illustrating the head mounted display of FIG. 9.

Referring to FIGS. 9 and 10, a head mounted display 1000 according to an embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user’s left eye, and the second display device 10_2 provides an image to the user’s right eye. Since each of the first display device 10_1 and the second display device 10_2 is substantially the same as the display device 10 described in conjunction with FIGS. 1 to 8, the description of the first display device 10_1 and the second display device 10_2 will be omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user’s left eye to the first display device 10_1, and may transmit the digital video data DATA corresponding to a right-eye image optimized for the user’s right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is located such that the housing cover 1200 covers one open surface of the display device housing 1100. The housing cover 1200 may include the first eyepiece 1210 at which the user’s left eye is located and the second eyepiece 1220 at which the user’s right eye is located. FIGS. 9 and 10 illustrate that the first eyepiece 1210 and the second eyepiece 1220 are located separately, but embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

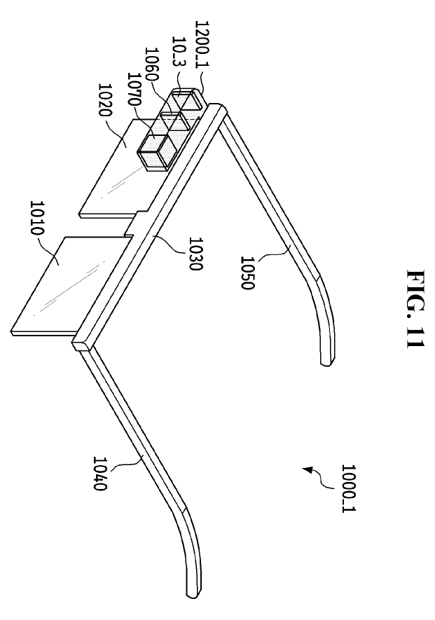

The head mounted band 1300 serves to secure the display device housing 1100 to the user's head such that the first eyepiece 1210 and the second eyepiece 1220 of the housing cover 1200 remain located on the user’s left and right eyes, respectively. In an example in which the display device housing 1100 is implemented to be lightweight and compact, the head mounted display 1000 may be provided with, as illustrated in FIG. 11, an eyeglass frame instead of the head mounted band 1300.

FIG. 11 is a perspective view illustrating another example of a head mounted display.

Referring to FIG. 11, a head mounted display 1000_1 according to an embodiment may be an eyeglasses-type display device in which a display device housing 1200_1 is implemented in a lightweight and compact manner. The head mounted display 1000_1 according to an embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user’s right eye through the right eye lens 1020 after the optical path is changed by the optical path changing member 1070. As a result, the user may view an augmented reality image, through the right eye, in which a virtual image displayed on the display device 10_3 and a real image seen through the right eye lens 1020 are combined.

FIG. 11 illustrates that the display device housing 1200_1 is located at the right end of the support frame 1030, but embodiments of the present disclosure are not limited thereto. For example, the display device housing 1200_1 may be located at the left end of the support frame 1030, and in this case, the image of the display device 10_3 may be provided to the user's left eye. Alternatively, the display device housing 1200_1 may be located at both the left and right ends of the support frame 1030, and in this case, the user may view the image displayed on the display device 10_3 through both the left and right eyes.

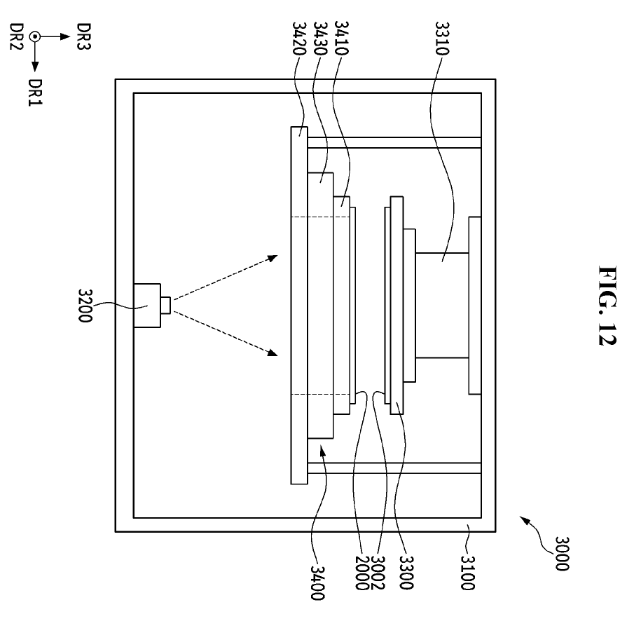

FIG. 12 is a schematic diagram illustrating a deposition apparatus according to an embodiment.

Referring to FIG. 12, a deposition apparatus 3000 may be used to form light emitting material layers on a backplane substrate 3002 in a manufacturing process of the display panel 100 (see FIG. 1). For example, as illustrated in FIG. 7, the semiconductor backplane SBP and the light emitting element backplane EBP may be located on the backplane substrate 3002, and the reflective electrode layer RL and the tenth interlayer insulating film INS10 may be located on the light emitting element backplane EBP. An eleventh interlayer insulating film INS11 may be located on the tenth interlayer insulating film INS10, electrode patterns, for example, anode electrodes AND may be located on the eleventh interlayer insulating film INS11, and the anode electrodes and may be electrically connected to the reflective electrode layer RL through the tenth vias VA10. The deposition apparatus 3000 may be used to form the light emitting stack IL on the electrode patterns.

The deposition apparatus 3000 may include a deposition source 3200 for providing a vapor deposition material on the backplane substrate 3002, a deposition mask 2000 located above the deposition source 3200, and a substrate chuck 3300 located above the deposition mask 2000 to support the backplane substrate 3002 such that the backplane substrate 3002 faces the deposition mask 2000. That is, the substrate chuck 3300 may support the backplane substrate 3002 such that the front surface of the backplane substrate 3002 faces downward, and may position the backplane substrate 3002 above the deposition mask 2000 to perform a deposition process. The substrate chuck 3300 may be supported by the support member 3310, and a permanent magnet (not illustrated) may be located inside the support member 3310.

The deposition source 3200, the deposition mask 2000, and the substrate chuck 3300 may be located in a process chamber 3100. The process chamber 3100 may have an internal space, and a deposition process for forming a deposition material layer on the backplane substrate 3002 may be performed in the internal space of the process chamber 3100. Although not illustrated, the process chamber 3100 may be connected to a vacuum pump (not illustrated), and the internal space of the process chamber 3100 may be set to a vacuum atmosphere by the vacuum pump. An opening (not illustrated) for the carry-in and carry-out of the backplane substrate 3002 and the deposition mask 2000 may be provided in a wall of the process chamber 3100, and the opening may be opened and closed by a gate valve (not illustrated).

A deposition material may be accommodated in the deposition source 3200. The deposition source 3200 may evaporate a deposition material such as an organic material, an inorganic material, a conductive material, or the like toward the backplane substrate 3002, and the evaporated deposition material may be deposited on the backplane substrate 3002 through the deposition mask 2000. For example, the deposition source 3200 may evaporate an organic material for forming light emitting material layers and emit the evaporated organic material toward the backplane substrate 3002, and the evaporated organic material may be deposited on the electrode patterns on the backplane substrate 3002 through the deposition mask 2000. Since deposition material (i.e., the evaporated organic material) emitted from the deposition source 3200 may be deposited on the backplane substrate 3002 passing through the deposition mask 2000, the deposition source 3200 may be located below the deposition mask 2000. The deposition source 3200 may be located below the central area of the deposition mask 2000.

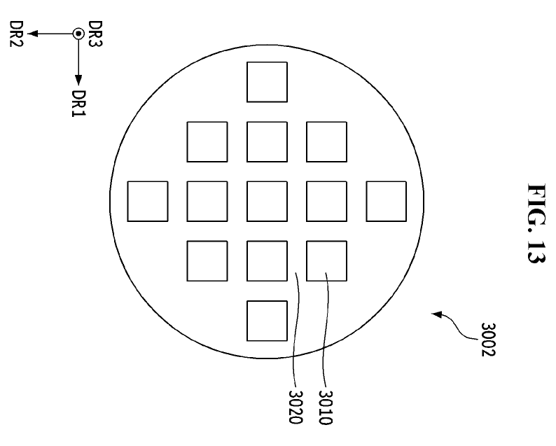

FIG. 13 is a schematic bottom view illustrating the backplane substrate illustrated in FIG. 12.

Referring to FIG. 13, the backplane substrate 3002 may include a plurality of display cell regions 3010 and a scribe lane region 3020 located between the display cell regions 3010. The display cell regions 3010 may be arranged in a matrix form along the first direction DR1 and the second direction DR2 as illustrated in FIG. 13, and each of the display cell regions 3010 may be individualized into a plurality of display panels 100 (see FIG. 1) by a dicing process after the display manufacturing process is completed. For example, the display cell regions 3010 may be arranged in a matrix form along the first horizontal direction DR1 and the second horizontal direction DR2 perpendicular to the first horizontal direction DR1.

Each of the display cell regions 3010 may include the semiconductor backplane SBP, the light emitting element backplane EBP located on the semiconductor backplane SBP, the reflective electrode layer RL located on the light emitting element backplane EBP, and the eleventh interlayer insulating film INS11 located on the reflective electrode layer RL. In some aspects, each of the display cell regions 3010 may include the plurality of electrode patterns, for example, the plurality of anode electrodes and located on the eleventh interlayer insulating film INS11, and the anode electrodes and may be connected to the reflective electrode layer RL through the plurality of vias VA10. In this case, the electrode patterns of the display cell regions 3010 may be located on the front surface of the backplane substrate 3002, and the substrate chuck 3300 may hold the rear surface of the backplane substrate 3002 such that the electrode patterns of the display cell regions 3010 face downward, i.e., face the deposition source 3200.

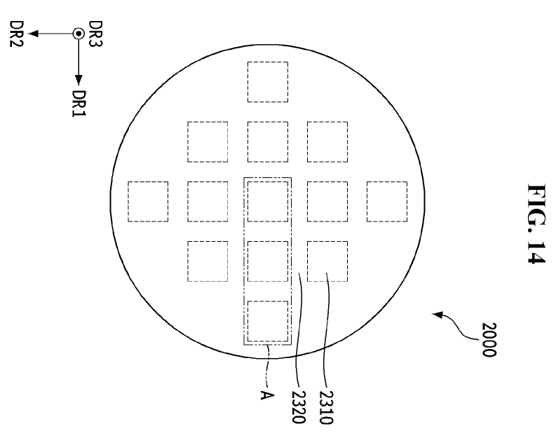

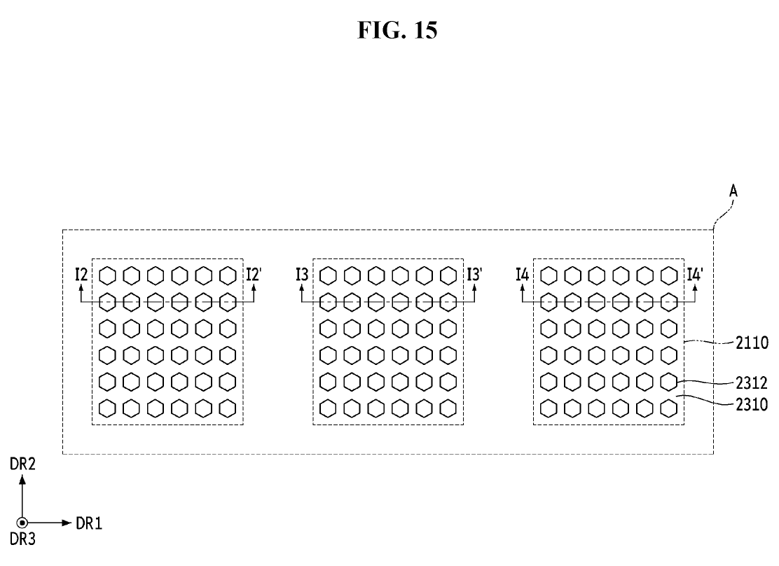

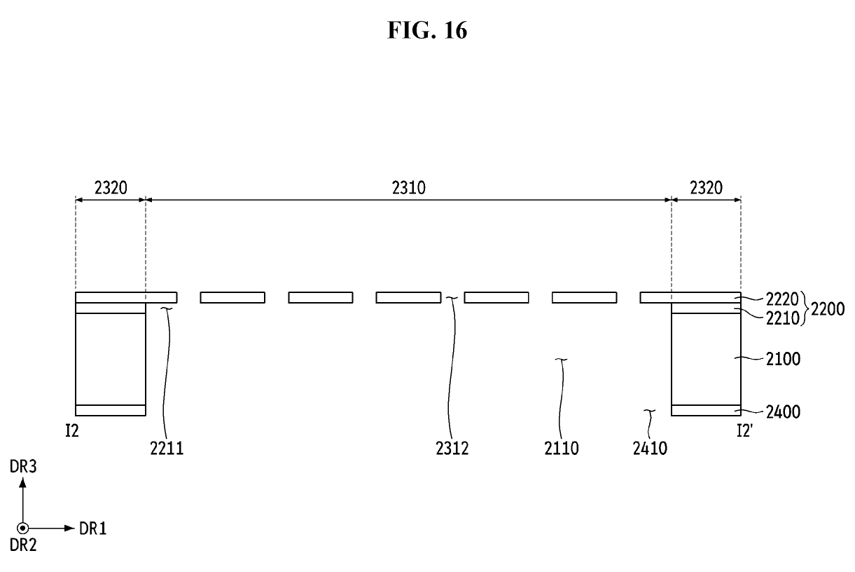

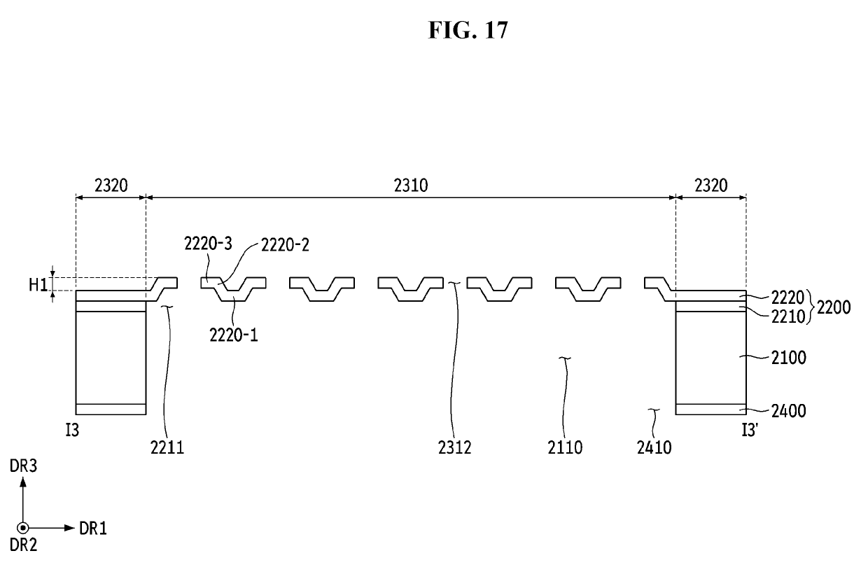

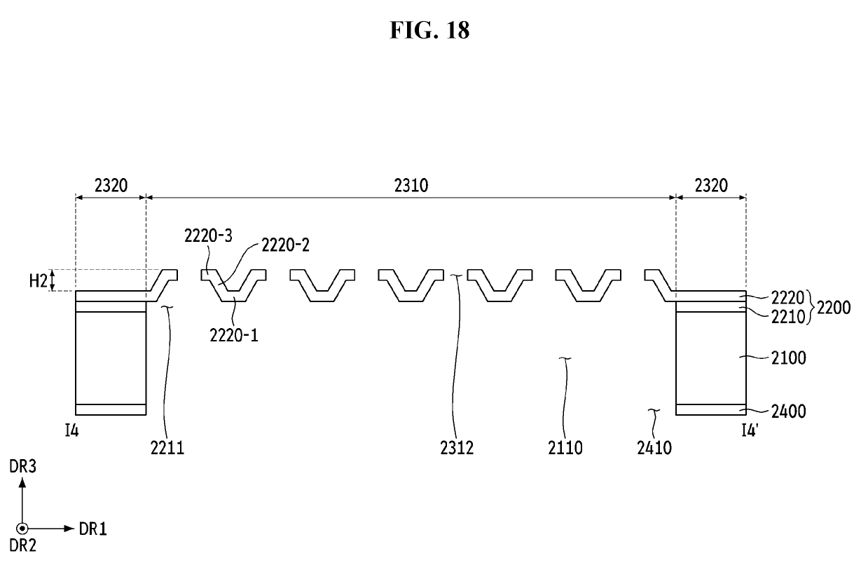

FIG. 14 is a schematic plan view illustrating a deposition mask according to an embodiment of the present disclosure. FIG. 15 is an enlarged view of part A of FIG. 14. FIG. 16 is a cross-sectional view taken along line I2-I2’ of FIG. 15. FIG. 17 is a cross-sectional view taken along line I3-I3’ of FIG. 15. FIG. 18 is a cross-sectional view taken along line I4-I4’ of FIG. 15.

Referring to FIGS. 14 to 18, a deposition mask 2000 according to an embodiment of the present disclosure may include a mask frame 2100, a membrane 2200, and a rear inorganic layer 2400.

The mask frame 2100 may have cell openings 2110. The mask frame 2100 may be provided as a single crystal silicon substrate, and the cell openings 2110 may be formed by a wet etching process using tetramethyl ammonium hydroxide (TMAH), or potassium hydroxide (KOH). The crystal orientation of the single crystal silicon substrate provided as the mask frame 2100 may be in the third direction DR3.

The cell openings 2110 are areas where a portion of the mask frame 2100 is removed, and the cell openings 2110 may extend in the thickness direction of the mask frame 2100 from the bottom surface of the mask frame 2100 and penetrate the mask frame 2100. In some embodiments, the cell openings 2110 may extend toward the membrane 2200 from the bottom surface of the mask frame 2100 and penetrate the mask frame 2100. The cell openings 2110 may be arranged in a matrix form along the first horizontal direction DR1 and the second horizontal direction DR2 perpendicular to the first horizontal direction DR1. For example, one cell opening 2110 among the plurality of cell openings 2110 may be located in the central portion of the mask frame 2100, and the other cell openings 2110 may be arranged such that the other cell openings 2110 are spaced apart from the one cell opening 2110 located in the central portion of the mask frame 2100 toward the edge side of the mask frame 2100.

The membrane 2200 may be located above the mask frame 2100. The membrane 2200 may include the mask cell regions 2310 respectively corresponding to the display cell regions 3010 of the backplane substrate 3002 and a grid region 2320 excluding the mask cell regions 2310. The mask cell regions 2310 may be located above the cell openings 2110, and the grid region 2320 may be located above the mask frame 2100 excluding the cell openings 2110. A plurality of pixel openings 2312 overlapping the cell openings 2110 may be formed in the membrane 2200.

The membrane 2200 may include an inorganic layer 2210 and a nitride layer 2220.

The inorganic layer 2210 may be located above the mask frame 2100. In some embodiments, the inorganic layer 2210 may be located above the mask frame 2100 such that the bottom surface of the inorganic layer 2210 is in contact with the top surface of the mask frame 2100. The inorganic layer 2210 may include a material that has an etching selectivity with respect to the nitride layer 2220 and the mask frame 2100. For example, the inorganic layer 2210 may include silicon oxide (SiOₓ).

A plurality of inorganic layer openings 2211 may be formed in the inorganic layer 2210. The inorganic layer openings 2211 may be regions where a portion of the inorganic layer 2210 is removed. The inorganic layer openings 2211 may be formed by a wet etching process using tetramethyl ammonium hydroxide (TMAH), or potassium hydroxide (KOH). The inorganic layer openings 2211 may be connected to the cell openings 2110.

The nitride layer 2220 may be located on the inorganic layer 2210. In some embodiments, the nitride layer 2220 may be located on the inorganic layer 2210 such that the bottom surface of the nitride layer 2220 is in contact with the top surface of the inorganic layer 2210. The nitride layer 2220 may include silicon nitride (SiNₓ).

A plurality of pixel openings 2312 may be formed in the nitride layer 2220. The plurality of pixel openings 2312 may be an area where a portion of the nitride layer 2220 is removed. The plurality of pixel openings 2312 may expose anode electrodes and in a deposition process. The plurality of pixel openings 2312 may be exposed toward a deposition source 3200 (see FIG. 12) through an inorganic layer opening 2211 and the cell opening 2110. The plurality of pixel openings 2312 may be connected to the cell opening 2110 through the inorganic layer opening 2211. The plurality of pixel openings 2312 may overlap the cell openings 2110 on the mask cell region 2310.

The rear inorganic layer 2400 may be located below the mask frame 2100. In some embodiments, the rear inorganic layer 2400 may be located below the mask frame 2100 such that the top surface of the rear inorganic layer 2400 is in contact with the bottom surface of the mask frame 2100. Rear openings 2410 connected to the cell openings 2110 may be formed in the rear inorganic layer 2400. The rear inorganic layer 2400 may include the same material as the inorganic layer 2210 of the membrane 2200. For example, the rear inorganic layer 2400 may include silicon oxide (SiOx).

The pixel openings 2312 that overlap the cell openings 2110 formed in the region different from the central area of the mask frame 2100 may be positioned higher than the pixel openings 2312 that overlap the cell openings 2110 formed in the central area of the mask frame 2100. In an example embodiment, the plurality of cell openings 2110 may include a first cell opening 2110 formed in a central area of the mask frame 2100, a second cell opening 2110 formed in an edge region of the mask frame 2100, and a third cell opening 2110 formed between the first cell opening 2110 and the second cell opening 2110. The cell opening 2110 formed in the central area of the mask frame 2100 may be the first cell opening 2110, and the cell openings 2110 formed in the region different from the central area of the mask frame 2100 may be the second cell opening 2110 and the third cell opening 2110. The cell opening 2110 formed in the central area of the mask frame 2100 may be a cell opening 2110 formed in a region overlapping the deposition source 3200 (see FIG. 12), and the cell openings 2110 formed in the region different from the central area of the mask frame 2100 may be cell openings 2110 formed in a region different from the region overlapping the central area of the deposition source 3200 (see FIG. 12). The cell opening 2110 formed in the region overlapping the deposition source 3200 (see FIG. 12) may be the first cell opening 2110, and the cell openings 2110 formed in the region different from the region overlapping the deposition source 3200 (see FIG. 12) may be the second cell opening 2110 and the third cell opening 2110.

Referring to FIG. 16, the pixel openings 2312 formed on the top portion of the first cell opening 2110 may be located on the same imaginary horizontal surface as the membrane 2200 located in the grid region 2320. Descriptions herein of an opening (e.g., a pixel opening 2312) being formed on a top portion of another opening (e.g., an opening 2110) may refer to the opening being higher than or above the top portion of the other opening. In some embodiments, the pixel openings 2312 formed in the mask cell region 2310 located in the central area of the mask frame 2100 may be located on the same imaginary horizontal surface as the nitride layer 2220 located in the grid region 2320. For example, the upper ends of the pixel openings 2312 formed on the top portion of the first cell opening 2110 may be located on the same imaginary horizontal surface as the top surface of the nitride layer located in the grid region 2320, and the lower ends of the pixel openings 2312 formed on the top portion of the first cell opening 2110 may be located on the same imaginary horizontal surface as the bottom surface of the nitride layer 2220 located in the grid region 2320.

Referring to FIG. 17, the pixel openings 2312 formed on the top portion of the third cell opening 2110 may be located on the top portion of the membrane 2200 located in the grid region 2320. In some embodiments, the pixel openings 2312 formed in the mask cell region 2310 located in the region different from the central area of the mask frame 2100 may be located higher than the nitride layer 2220 located in the grid region 2320. For example, the lower ends of the pixel openings 2312 formed on the top portion of the third cell opening 2110 may be located higher than the top surface of the nitride layer 2220 located in the grid region 2320. The pixel openings 2312 overlapping the third cell opening 2110 may be located higher than the top portion of the pixel openings 2312 overlapping the first cell opening 2110.

The nitride layer 2220 of the membrane 2200 overlapping the third cell opening 2110 may include lower flat portions 2220-1, connection portions 2220-2, and upper flat portions 2220-3.

The lower flat portions 2220-1 may be located on the same imaginary horizontal surface as the nitride layer 2220 located in the grid region 2320. For example, the top surfaces of the lower flat portions 2220-1 may be located on the same imaginary horizontal surface as the top surface of the nitride layer 2220 located in the grid region 2320, and the bottom surfaces of the lower flat portions 2220-1 may be located on the same imaginary horizontal surface as the bottom surface of the nitride layer 2220 located in the grid region 2320.

The upper flat portions 2220-3 may be located higher than the top portion of the nitride layer 2220 located in the grid region 2320. For example, the bottom surfaces of the upper flat portions 2220-3 may be located higher than the top surface of the nitride layer 2220 located in the grid region 2320. A plurality of pixel openings 2312 may be formed in the upper flat portions 2220-3.

The upper flat portions 2220-3 may be located above the lower flat portions 2220-1 by a first height H1. For example, the upper flat portions 2220-3 may have the same thickness as the lower flat portions 2220-1, and the top surfaces of the upper flat portions 2220-3 may be located above the top surfaces of the lower flat portions 2220-1 by the first height H1.

The connection portions 2220-2 may connect the lower flat portions 2220-1 and the upper flat portions 2220-3. The connection portions 2220-2 may extend obliquely from the lower flat portions 2220-1 toward the upper flat portions 2220-3 and connect the lower flat portions 2220-1 and the upper flat portions 2220-3.

Referring to FIG. 18, the pixel openings 2312 formed on the top portion of the second cell opening 2110 may be located higher than the top portion of the membrane 2200 located in the grid region 2320. In some embodiments, the pixel openings 2312 formed in the mask cell region 2310 located in the region different from the central area of the mask frame 2100 may be located higher than the nitride layer 2220 located in the grid region 2320. For example, the lower ends of the pixel openings 2312 formed on the top portion of the second cell opening 2110 may be located higher than the top surface of the nitride layer 2220 located in the grid region 2320. The pixel openings 2312 overlapping the second cell opening 2110 may be located higher than the top portion of the pixel openings 2312 overlapping the second cell opening 2110 and the third cell opening 2110.

The nitride layer 2220 of the membrane 2200 overlapping the second cell opening 2110 may include lower flat portions 2220-1, connection portions 2220-2, and upper flat portions 2220-3.

The lower flat portions 2220-1 may be located on the same imaginary horizontal surface as the nitride layer 2220 located in the grid region 2320. For example, the top surfaces of the lower flat portions 2220-1 may be located on the same imaginary horizontal surface as the top surface of the nitride layer 2220 located in the grid region 2320, and the bottom surfaces of the lower flat portions 2220-1 may be located on the same imaginary horizontal surface as the bottom surface of the nitride layer 2220 located in the grid region 2320.

The upper flat portions 2220-3 may be located higher than the top portion of the nitride layer 2220 located in the grid region 2320. For example, the bottom surfaces of the upper flat portions 2220-3 may be located higher than the top surface of the nitride layer 2220 located in the grid region 2320. A plurality of pixel openings 2312 may be formed in the upper flat portions 2220-3.

The upper flat portions 2220-3 may be located above the lower flat portions 2220-1 by a second height H2. For example, the upper flat portions 2220-3 may have the same thickness as the lower flat portions 2220-1, and the top surfaces of the upper flat portions 2220-3 may be located above the top surfaces of the lower flat portions 2220-1 by the second height H2.

The connection portions 2220-2 may connect the lower flat portions 2220-1 and the upper flat portions 2220-3. The connection portions 2220-2 may extend obliquely from the lower flat portions 2220-1 toward the upper flat portions 2220-3 and connect the lower flat portions 2220-1 and the upper flat portions 2220-3.

The pixel openings 2312 positioned above the third cell opening 2110 illustrated in FIG. 17 may be positioned above the pixel openings 2312 positioned above the first cell opening 2110 illustrated in FIG. 16, and may be positioned below the pixel openings 2312 positioned above the second cell opening 2110 illustrated in FIG. 18. Accordingly, the first height H1 from the lower flat portions 2220-1 located on the top portion of the third cell opening 2110 to the upper flat portions 2220-3 may be smaller than the second height H2 from the lower flat portions 2220-1 located on the top portion of the second cell opening 2110 to the upper flat portions 2220-3. Since the pixel openings 2312 located on the upper side of the third cell openings 2110 are located higher than the pixel openings 2312 located on the top portion of the first cell opening 2110 and lower than the pixel openings 2312 located on the top portion of the second cell opening 2110, the pixel openings 3212 may be arranged to be closer to the backplane substrate 3002 (see FIG. 12) from the central area to the edge region of the mask frame 2100.

Since a space is formed between the backplane substrate 3002 (see FIG. 12) and the deposition mask 2000, and the deposition source 3200 (see FIG. 12) is placed below the central area of the deposition mask 2000, the deposition material that passed through the cell openings 2110 may be deposited beyond the display cell region 3010 (see FIG. 13) as the deposition material passes through the cell openings 2110 from the central area to the edge region of the of the deposition mask 2000. However, since the pixel openings 2312 of the deposition mask 2000 of the present invention are arranged closer to the backplane substrate 3002 (see FIG. 12) from the central area of the mask frame 2100 to the edge region, the deposition material passing through the cell openings 2110 formed in the region different from the region overlapping the deposition source 3200 (see FIG. 12) may be deposited in the display cell region 3010 (see FIG. 13) of the backplane substrate 3002 (see FIG. 12).

Hereinafter, a method of manufacturing a deposition mask according to an embodiment of the present disclosure will be explained with reference to the drawing.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be provided,” “may be prepared,” “may be disposed,” “may be formed,” and the like include methods, processes, and techniques for providing, preparing, disposing, forming the element, and the like in accordance with example aspects described herein.

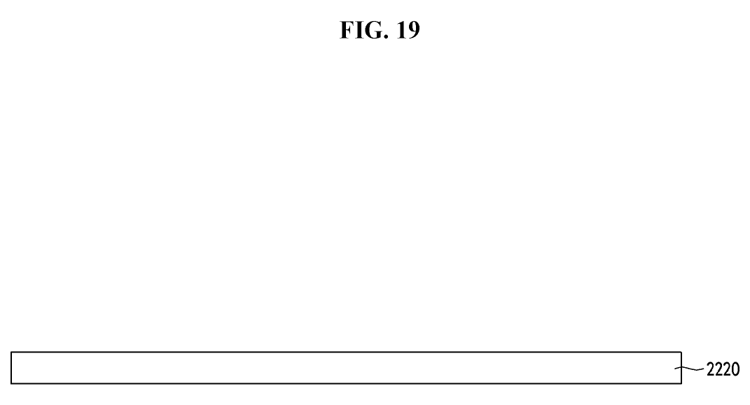

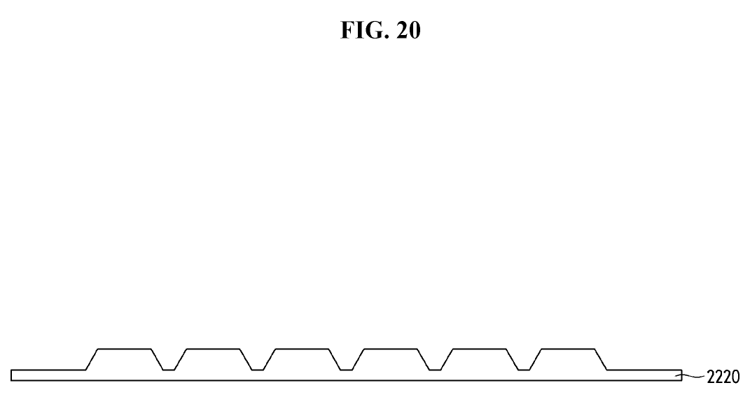

FIG. 19 is a view illustrating a step of preparing a nitride layer in a method of manufacturing a deposition mask according to an embodiment according to the present disclosure. FIG. 20 is a view illustrating a state in which a part of the nitride layer is removed in FIG. 19.

Referring to FIGS. 19 and 20, a nitride layer 2220 having a predetermined thickness may be provided. The nitride layer 2220 may include silicon nitride (SiNx). Like described herein, when the nitride layer 2220 is prepared, a part of the top portion of the nitride layer 2220 may be removed. The part of the top portion of the nitride layer 2220 may be removed by a wet etching process using tetramethyl ammonium hydroxide (TMAH), or potassium hydroxide (KOH).

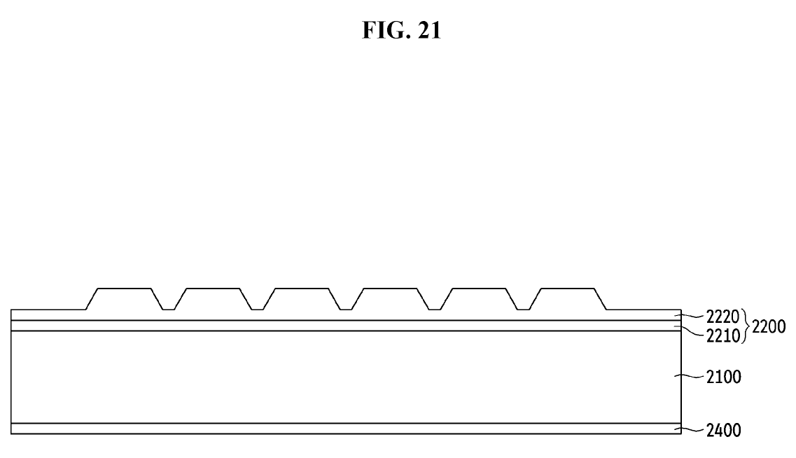

FIG. 21 is a view illustrating a state in which an inorganic layer, a mask frame, and a rear inorganic layer are formed in FIG. 20.

Referring to FIG. 21, after a portion of the upper side of the nitride layer 2220 is removed, an inorganic layer 2210 may be placed on the bottom portion of the nitride layer 2220, a mask frame 2100 may be placed on the bottom portion of the inorganic layer 2210, and a rear inorganic layer 2400 may be placed the bottom portion of the mask frame 2100. The inorganic layer 2210, the mask frame 2100, and the rear inorganic layer 2400 located on the bottom portion of the nitride layer 2220 may be placed by a deposition process. The inorganic layer 2210 and the rear inorganic layer 2400 may include silicon oxide (SiOx).

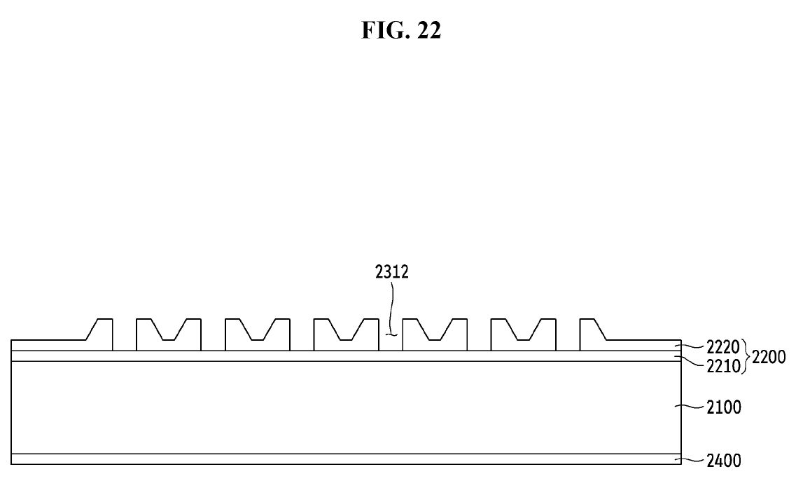

FIG. 22 is a view illustrating a state in which a pixel opening is formed in FIG. 21.

Referring to FIG. 22, after the inorganic layer 2210, the mask frame 2100, and the rear inorganic layer 2400 are placed on the bottom portion of the nitride layer 2220, a plurality of pixel openings 2312 may be formed in the nitride layer 2220. The pixel openings 2312 may be formed by penetrating the nitride layer 2220. The pixel openings 2312 may be formed in the nitride layer 2220 by a wet etching process using tetramethyl ammonium hydroxide (TMAH), or potassium hydroxide (KOH).

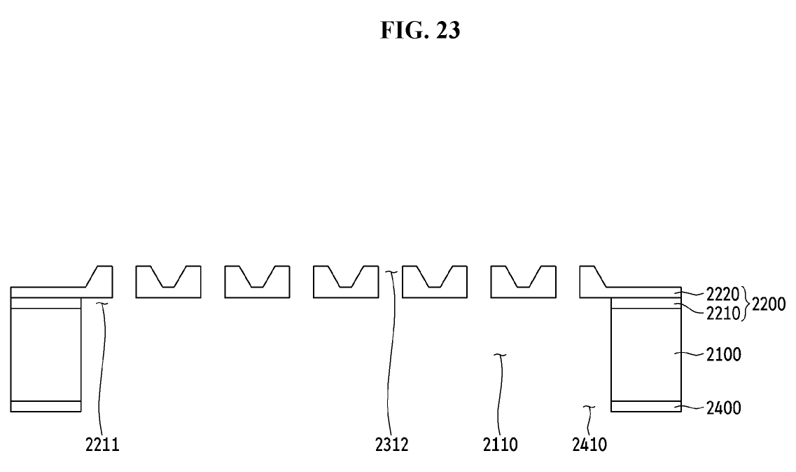

FIG. 23 is a view illustrating a state in which an inorganic layer opening, a cell opening, and a rear opening are formed in FIG. 22.

Referring to FIG. 23, after forming the plurality of pixel openings 2312 in the nitride layer 2220, an inorganic layer opening 2211 may be formed in the inorganic layer 2210, a cell opening 2110 may be formed in the mask frame 2100, and a rear opening 2410 may be formed in the rear inorganic layer 2400.

The inorganic layer opening 2211 may penetrate a part of the inorganic layer 2210 to be formed, the cell opening 2110 may be penetrate a part of the mask frame 2100 to be formed, and the rear opening 2410 may penetrate the rear inorganic layer 2400 to be formed.

The inorganic layer opening 2211, the cell opening 2110, and the rear opening 2410 may be formed in the inorganic layer 2210, the mask frame 2100, and the rear inorganic layer 2400, respectively, by a wet etching process using tetramethyl ammonium hydroxide (TMAH), or potassium hydroxide (KOH).

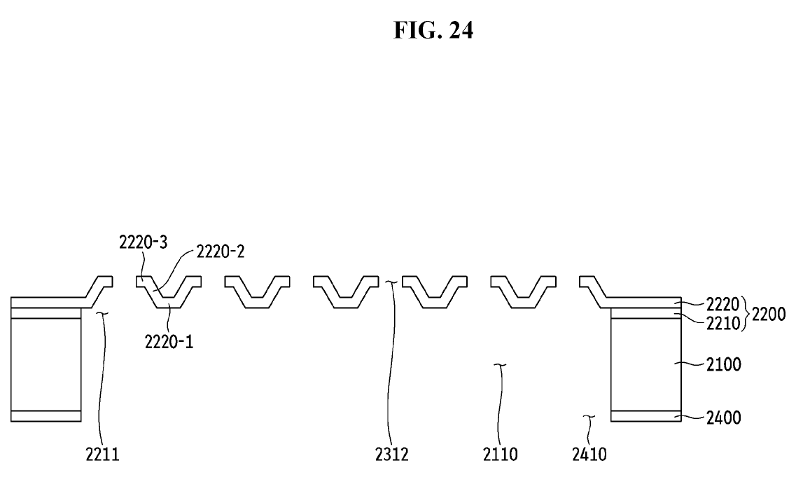

FIG. 24 is a view illustrating a state in which a part of the nitride layer is removed in FIG. 23.

Referring to FIG. 24, a part of the lower side of the nitride layer 2220 may be removed. The part of the lower side of the nitride layer 2220 may be removed by a wet etching process using tetramethyl ammonium hydroxide (TMAH), or potassium hydroxide (KOH). As described herein, as the part of the lower side of the nitride layer 2220 is removed, a lower flat portion 2220-1, a connection portion 2220-2, and an upper flat portion 2220-3 may be formed.

The display device according to the embodiment may be applied to various electronic devices. The electronic device according to an embodiment may include the display device described herein, and may further include a module or device having an additional function in addition to the display device.

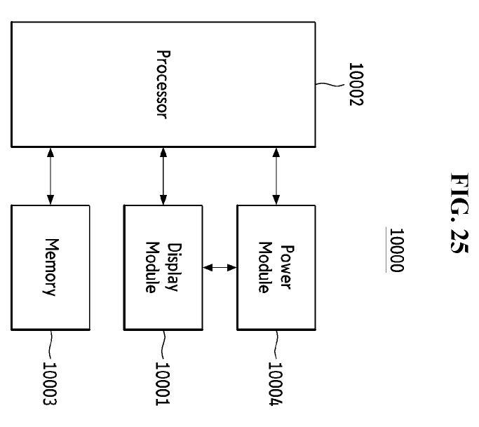

FIG. 25 is a block diagram of an electronic device according to an embodiment.

Referring to FIG. 25, an electronic device 10000 according to an embodiment may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), or a controller.

The memory 10003 may store data information supportive of the operation of the processor 10002 or the display module 10001. In an example in which the processor 10002 executes an application stored in the memory 10003, an image data signal and/or an input control signal is transmitted to the display module 10001, and the display module 10001 may process the received signal and output image information through a display screen.

The power module 10004 may include a power supply module, such as a power adapter or a battery device, and a power conversion module that converts power supplied by the power supply module to generate power for the operation of the electronic device 10000.

At least one of the components of the electronic device 10000 described herein may be included in the display device according to the embodiments described herein. Further, some of individual modules functionally included in one module may be included in the display device and some others may be provided separately from the display device. For example, the display device may include the display module 10001, and the processor 10002, the memory 10003, and the power module 10004 may be provided in the form of other devices in the electronic device 10000 different from the display device.

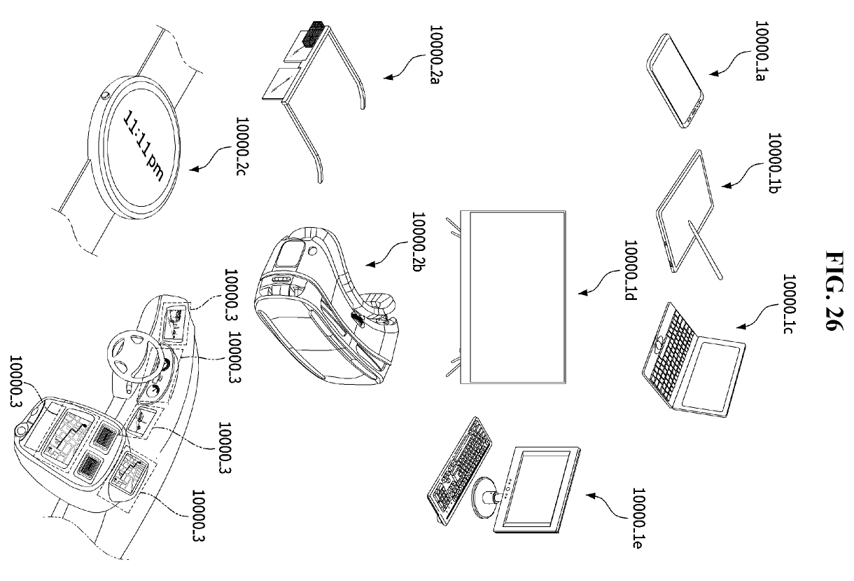

FIG. 26 is schematic views of electronic devices according to various embodiments.

Referring to FIG. 26, various electronic devices to which the display devices according to the embodiments are applied may include not only an image display electronic device such as a smartphone 10000_1a, a tablet PC 10000_1b, a laptop 10000_1c, a TV 10000_1d, and a desk monitor 10000_1e, but also a wearable electronic device including a display module such as smart glasses 10000_2a, a head mounted display 10000_2b, and a smart watch 10000_2c, and a vehicle electronic device 10000_3 including a display module such as a room mirror display, a center information display (CID) placed on a dashboard, a center fascia, and an instrument panel of a car.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A deposition mask comprising:
a mask frame in which a plurality of cell openings are formed; and
a membrane located above the mask frame and in which a plurality of pixel openings overlapping the plurality of cell openings are formed,
wherein, among the plurality of pixel openings and the plurality of cell openings, pixel openings overlapping cell openings formed in a region different from a central area of the mask frame are located higher than pixel openings overlapping cell openings formed in the central area of the mask frame.

2. The deposition mask of claim 1, wherein:
the membrane is divided into:
a plurality of mask cell regions located on top portions of the plurality of cell openings, and
a grid region located on a top portion of the mask frame excluding the plurality of cell openings, and
the plurality of pixel openings are formed in the plurality of mask cell regions.

3. The deposition mask of claim 2, wherein, among the plurality of pixel openings and the plurality of mask cell regions, pixel openings formed in a mask cell region located in a central area of the mask frame are located on a same imaginary horizontal surface as a portion of the membrane located in the grid region.

4. The deposition mask of claim 2, wherein, among the plurality of pixel openings and the plurality of mask cell regions, pixel openings formed in the mask cell regions located in a region different from the central area of the mask frame are located higher than a portion of the membrane located in the grid region.

5. The deposition mask of claim 1, wherein:
the plurality of cell openings comprise:
a first cell opening formed in a central area of the mask frame;
a second cell opening formed in an edge portion of the mask frame; and
a third cell opening formed between the first cell opening and the second cell opening, and
among the plurality of pixel openings, pixel openings overlapping the second cell opening are located higher than pixel openings overlapping the first cell opening and the third cell opening.

6. The deposition mask of claim 5, wherein, among the plurality of pixel openings, the pixel openings overlapping the third cell opening are located higher than top portions of the pixel openings overlapping the first cell opening and lower than bottom portions of the pixel openings overlapping the second cell opening.

7. The deposition mask of claim 2, wherein:
a portion of the membrane overlaps a cell opening formed in the region different from a central area of the mask frame and comprises a plurality of upper flat portions located higher than a top portion of the membrane located in the grid region, and
the plurality of pixel openings are formed in the plurality of upper flat portions.

8. The deposition mask of claim 7, wherein:
the portion of the membrane which overlaps the cell opening formed in the region different from the central area of the mask frame further comprises a plurality of lower flat portions located on a same imaginary horizontal surface as the top portion of the membrane located in the grid region; and
a plurality of connection portions connecting the plurality of upper flat portions and the plurality of lower flat portions.

9. The deposition mask of claim 1, wherein:
the membrane comprises:
an inorganic layer located on a top portion of the mask frame; and
a nitride layer located on a top portion of the inorganic layer, and
the plurality of pixel openings are formed in the nitride layer.

10. The deposition mask of claim 9, wherein, in the inorganic layer, the plurality of cell openings and a plurality of inorganic layer openings are formed.

11. The deposition mask of claim 1, further comprising a rear inorganic layer located on a bottom portion of the mask frame,
wherein, in the rear inorganic layer, a plurality of rear openings overlapping the plurality of cell openings are formed.

12. A deposition device comprising:
a deposition mask; and
a deposition source located below the deposition mask and emitting a deposition material toward the deposition mask,
wherein:
the deposition mask comprises:
a mask frame in which a plurality of cell openings are formed; and
a membrane located on a top portion of the mask frame and in which a plurality of pixel openings overlapping the plurality of cell openings are formed, and
among the plurality of pixel openings, pixel openings formed in a region different from a region overlapping the deposition source are located higher than pixel openings formed in the region overlapping the deposition source.

13. The deposition device of claim 12, wherein:
the membrane is divided into:
a plurality of mask cell regions located on top portions of the plurality of cell openings, and
a grid region located on a top portion of the mask frame excluding the plurality of cell openings, and
the plurality of pixel openings are formed in the plurality of mask cell regions.

14. The deposition device of claim 13, wherein, among the plurality of pixel openings and the plurality of mask cell regions, pixel openings formed in a mask cell region located in the region overlapping the deposition source are located on a same imaginary horizontal surface as a portion of the membrane located in the grid region.

15. The deposition device of claim 13, wherein, among the plurality of pixel openings and the plurality of mask cell regions, pixel openings formed in mask cell regions located in the region different from the region overlapping the deposition source are located higher than a portion of the membrane located in the grid region.

16. The deposition device of claim 12, wherein:
the plurality of cell openings comprises:
a first cell opening formed in the region overlapping the deposition source;
a second cell opening formed in an edge region of the mask frame; and
a third cell opening formed between the first cell opening and the second cell opening, and
among the plurality of pixel openings, pixel openings overlapping the second cell opening are located higher than pixel openings overlapping the first cell opening and the third cell opening.

17. The deposition device of claim 16, wherein, among the plurality of pixel openings, the pixel openings overlapping the third cell opening are located higher than the pixel openings overlapping the first cell opening and lower than the pixel openings overlapping the second cell opening.

18. The deposition device of claim 13, wherein:
a portion of the membrane overlaps a cell opening formed in the region different from the region overlapping the deposition source comprises a plurality of upper flat portions located higher than the membrane located in the grid region, and
the plurality of pixel openings are formed in the plurality of upper flat portions.

19. The deposition device of claim 18, wherein:
the portion of the membrane which overlaps the cell opening formed in the region different from the region overlapping the deposition source further comprises:
a plurality of lower flat portions located on a same imaginary horizontal surface as a portion of the membrane located in the grid region; and
a plurality of connection portions connecting the plurality of upper flat portions and the plurality of lower flat portions.

20. An electronic device comprising:
a display device manufactured using a deposition mask,
wherein the deposition mask comprises:
a mask frame in which a plurality of cell openings are formed; and
a membrane located above the mask frame and in which a plurality of pixel openings overlapping the plurality of cell openings are formed,
wherein, among the plurality of pixel openings and the plurality of cell openings, pixel openings overlapping cell openings formed in a region different from a central area of the mask frame are located higher than pixel openings overlapping cell openings formed in the central area of the mask frame.
